(19) United States
(12) Patent Application Publication
(10) Pub. No.: US 2026/0052959 A1
(43) Pub. Date: Feb. 19, 2026

(54) TRANSISTOR DEVICE INCLUDING ENCLOSED VOIDS BELOW A CHANNEL REGION AND METHODS OF FORMING

(71) Applicant: Microchip Technology Incorporated, Chandler, AZ (US)

(72) Inventors: Steve Nagel, Chandler, AZ (US); Bomy Chen, Newark, CA (US)

(73) Assignee: Microchip Technology Incorporated, Chandler, AZ (US)

(21) Appl. No.: 18/926,409

(22) Filed: Oct. 25, 2024

Related U.S. Application Data
(60) Provisional application No. 63/684,417, filed on Aug. 18, 2024.

(51) Int. Cl. H01L 21/764; H01L 21/78; H01L 29/66; H01L 29/778

(52) U.S. Cl. CPC H01L 21/764; H01L 21/7806; H10D 30/015; H10D 30/475

(57) ABSTRACT

A method includes forming a semiconductor layer on a donor substrate, the semiconductor layer comprising a semiconductor material, forming an array of cavities in the semiconductor layer, bonding a transistor substrate to the semiconductor layer, wherein the transistor substrate encloses the array of cavities to form an array of enclosed voids, performing a separation process to separate (a) the transistor substrate and a first portion of the semiconductor layer including the array of enclosed voids from (b) the donor substrate and a second portion of the semiconductor layer, and using the transistor substrate and the first portion of the semiconductor layer to form a high-electron-mobility transistor (HEMT) device with a two-dimensional electron gas (2DEG) channel region over the array of enclosed voids.

### RELATED APPLICATION

This application claims priority to commonly owned United States Provisional Ser. No. 63/684,417 filed Aug. 18, 2024, the entire contents of which are hereby incorporated by reference for all purposes.

### TECHNICAL FIELD

The present disclosure relates to a transistor device (e.g., an HEMT device) including enclosed voids below a channel region (e.g., a two-dimensional electron gas (2DEG) channel region), and methods of forming such transistor device.

### BACKGROUND

In certain types of transistors, for example high-electron-mobility transistor (HEMT) devices, device capacitance, for example an output capacitance referred to as Cₒₛₛ, contributes to switching losses and reduces switching frequency of the transistor.

Accordingly, there is a need for reducing capacitance (for example, Cₒₛₛ output capacitance) in HEMT devices.

### SUMMARY

The present disclosure provides transistor devices (e.g., HEMT devices) including an array of enclosed voids formed below the channel, in particular below a two-dimensional electron gas (2DEG) channel region in the semiconductor buffer layer, and methods of forming such transistor devices. The enclosed voids may reduce an output capacitance (e.g., Cₒₛₛ) of the respective transistor device, thereby reducing switching losses, which may result in increased switching speed, increased efficiency, and reduced heat generation.

In some example, the transistor device may comprise any HEMT transistor with a compound semiconductor buffer layer, for example, comprising gallium nitride (GaN), aluminum gallium nitride (AlGaN), gallium arsenide (GaAs), or indium phosphide (InP).

In some examples, the array of enclosed voids may be formed in a lower portion of the semiconductor buffer layer. In some examples, the array of enclosed voids may be formed in the transistor substrate below the semiconductor buffer layer.

In some examples, the formation of enclosed voids may be enabled by a fabrication method including bonding of transferred layers rather than direct metal organic chemical vapor deposition (MOCVD) growth on the base wafer (substrate).

One aspect provides a method, including forming a semiconductor layer on a donor substrate, the semiconductor layer comprising a semiconductor material, forming an array of cavities in the semiconductor layer, bonding a transistor substrate to the semiconductor layer, wherein the transistor substrate encloses the array of cavities to form an array of enclosed voids, performing a separation process to separate (a) the transistor substrate and a first portion of the semiconductor layer including the array of enclosed voids from (b) the donor substrate and a second portion of the semiconductor layer, and using the transistor substrate and the first portion of the semiconductor layer to form a high-electron-mobility transistor (HEMT) device with a two-dimensional electron gas (2DEG) channel region over the array of enclosed voids.

In some examples, forming the HEMT transistor device comprises processing the first portion of the semiconductor layer including the array of enclosed voids to form a semiconductor buffer layer, and forming a gate dielectric layer over the semiconductor buffer layer to define the 2DEG channel region over the array of enclosed voids.

In some examples, processing the first portion of the semiconductor layer including the array of enclosed voids to form a semiconductor buffer layer comprises growing an additional thickness of the semiconductor material.

In some examples, the includes performing an ion implant at an implant depth in the semiconductor layer prior to bonding the transistor substrate to the semiconductor layer, wherein the separation process comprises performing an anneal to effect a separation of the semiconductor layer at the implant depth.

In some examples, the separation process comprises a mechanical cutting through the semiconductor layer.

In some examples, the method includes performing an etch process to form the array of cavities in the semiconductor layer.

In some examples, respective cavities in the array of cavities extend through a partial thickness of the semiconductor layer in a direction perpendicular to an interface between the semiconductor layer and the donor substrate.

In some examples, respective cavities are formed with a depth in the range of 50-500 nm in a direction perpendicular to an interface between the semiconductor layer and the donor substrate.

In some examples, the semiconductor layer comprises gallium nitride (GaN), aluminum gallium nitride (AlGaN), gallium arsenide (GaAs), or indium phosphide (InP).

One aspect provides a method, including forming a semiconductor layer on a donor substrate, the semiconductor layer comprising a semiconductor material, forming an array of cavities in a transistor substrate, bonding the transistor substrate including the array of cavities to the semiconductor layer, wherein the semiconductor layer encloses the array of cavities to form an array of enclosed voids, performing a separation process to separate (a) the transistor substrate including the array of enclosed voids and a first portion of the semiconductor layer from (b) the donor substrate and a second portion of the semiconductor layer, and using the transistor substrate including the array of enclosed voids and the first portion of the semiconductor layer to form a high-electron-mobility transistor (HEMT) device including a two-dimensional electron gas (2DEG) channel region over the array of enclosed voids.

In some examples, forming the HEMT transistor device comprises growing an additional thickness of the semiconductor material on the first portion of the semiconductor layer to form a semiconductor buffer layer, and forming a gate dielectric layer over the semiconductor buffer layer to define the 2DEG channel region over the array of enclosed voids in the transistor substrate.

In some examples, the method includes performing an ion implant at an implant depth in the semiconductor layer prior to bonding the transistor substrate to the semiconductor layer, wherein the separation process comprises performing an anneal to effect a separation of the semiconductor layer at the implant depth.

In some examples, the separation process comprises a mechanical cutting through the semiconductor layer.

One aspect provides a device including a semiconductor buffer layer formed on a substrate, a gate dielectric layer formed over the semiconductor buffer layer, a source, a drain, and a gate, wherein the gate dielectric layer defines a two-dimensional electron gas (2DEG) channel region in the semiconductor buffer layer, and an array of enclosed voids formed below the 2DEG channel region.

In some examples, the device comprises a high-electron-mobility transistor (HEMT) device.

In some examples, the array of enclosed voids are formed in the semiconductor buffer layer. In some examples, respective cavities in the array of cavities extend through a partial thickness of the semiconductor buffer layer in a direction perpendicular to an interface between the semiconductor buffer layer and the substrate.

In some examples, the array of enclosed voids are formed in the substrate. In some examples, respective cavities in the array of cavities extend through a partial thickness of the substrate in a direction perpendicular to an interface between the semiconductor buffer layer and the substrate.

In some examples, the semiconductor buffer layer comprises gallium nitride (GaN), aluminum gallium nitride (AlGaN), gallium arsenide (GaAs), or indium phosphide (InP).

### BRIEF DESCRIPTION OF THE DRAWINGS

Example aspects of the present disclosure are described below in conjunction with the figures, in which:

FIG. 1 is a cross-sectional side view of an example HEMT transistor device including enclosed voids formed in a semiconductor buffer layer below the 2DEG channel region of the HEMT transistor device;

FIGS. 2A-2G show a series of a cross-sectional side views illustrating an example method of forming the example HEMT transistor device shown in FIG. 1;

FIGS. 3A-3F show a series of a cross-sectional side views illustrating another example method of forming the example HEMT transistor device shown in FIG. 1;

FIG. 4 is a cross-sectional side view of an example HEMT transistor device including enclosed voids formed in a substrate below the 2DEG channel region; and

FIGS. 5A-5G show a series of a cross-sectional side views illustrating an example method of forming the example HEMT transistor device shown in FIG. 4.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

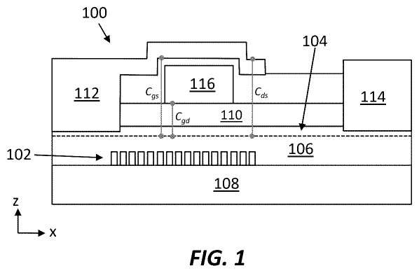

FIG. 1 is a cross-sectional side view of an example HEMT transistor device 100 including enclosed voids 102 formed below a 2DEG channel region 104, e.g., to reduce an output capacitance of the HEMT transistor device 100. The example HEMT transistor device 100 includes a semiconductor buffer layer 106 formed on a transistor substrate 108, a gate dielectric layer 110 formed over the semiconductor buffer layer 106, a source 112, a drain 114, and a gate 116, wherein the gate dielectric layer 110 formed over the semiconductor buffer layer 106 defines the 2DEG channel region 104 between the source 112 and drain 114.

In some examples, the transistor substrate 108 may comprise silicon carbide (SiC), high lattice defect density (HLDD) SiC, poly-SiC, or silicon; the semiconductor buffer region 106 may comprise gallium nitride (GaN), aluminum gallium nitride (AlGaN), gallium arsenide (GaAs), or indium phosphide (InP); and the gate dielectric layer 110 may comprise AlGaN, indium aluminum gallium nitride (InAlGaN), or Scandium aluminum nitride (ScAlN).

As shown, an array of enclosed voids 102 (e.g., vacuum sealed voids) may be formed in the semiconductor buffer layer 106 below the 2DEG channel region 104. The enclosed voids 102 may have any shape or shapes, e.g., elongated trenches (e.g., elongated in the x-direction or y-direction extending into the page), cylinders, etc. As shown, respective enclosed voids 102 may extend partially through the thickness of the semiconductor buffer layer 106 in a direction perpendicular to a planar interface PI between the semiconductor buffer layer 106 and underlying transistor substrate 108, i.e., in a vertical direction (z-direction) in the orientation shown in FIG. 1. In some examples, respective enclosed voids 102 have a vertical depth (i.e., in the z-direction) in the range of 50-500 nanometers (nm) (500-5000 angstroms (Å)). In addition, in some examples, the enclosed voids 102 may cover less than 50% of a lateral footprint (i.e., in the x-y plane) of a region of the semiconductor buffer layer 106 between the source 112 and drain 114.

The enclosed voids 102 may reduce at least a gate-drain capacitance C_{gd} and thus reduce an output capacitance Cₒₛₛ of the transistor device 100 (wherein Cₒₛₛ=C_{gd}+C_{ds}). Reducing Cₒₛₛ may reduce switching losses, which may provide increased switching speed, increased efficiency, and reduced heat generation.

In addition, as shown in FIG. 1, in some examples, the array of enclosed voids 102 may be located closer to the source 112 than the drain 114, which may reduce gate-source capacitance C_{gs}, thereby reducing an input capacitance Cᵢₛₛ of the transistor device 100 (wherein Cᵢₛₛ=C_{gs}+C_{gd}).

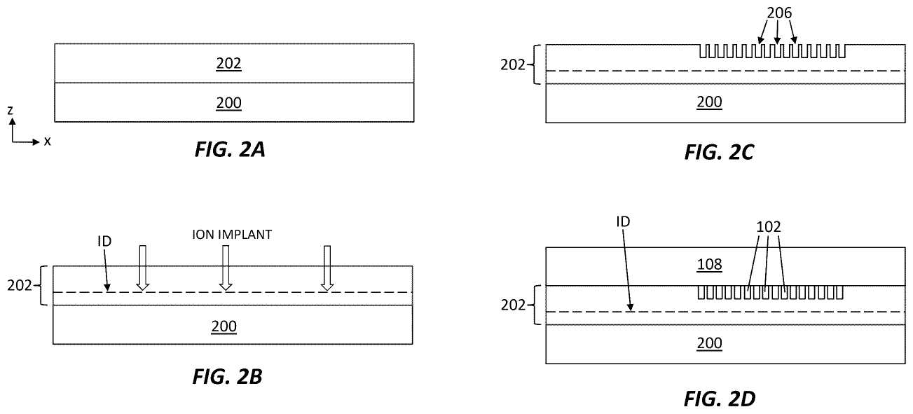

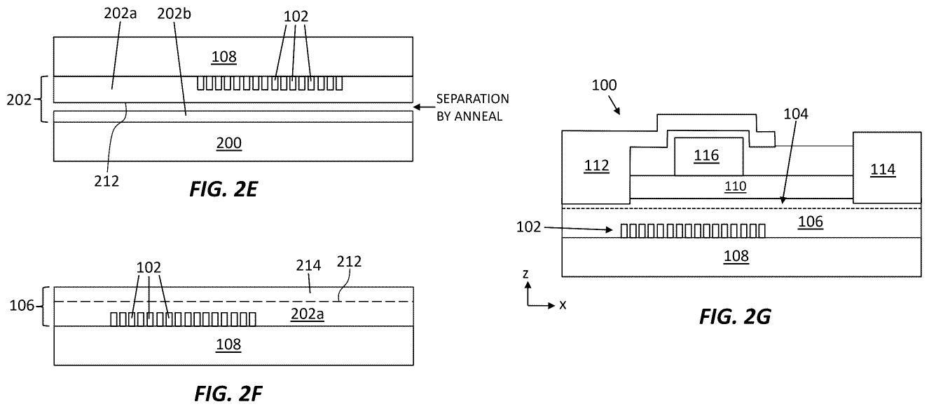

FIGS. 2A-2G show a series of a cross-sectional side views illustrating an example method of forming the example HEMT transistor device 100 shown in FIG. 1, i.e., including the array of enclosed voids 102 below the 2DEG channel region 104. As shown in FIG. 2A, a donor substate is provided, e.g., comprising silicon, silicon carbide (SiC), sapphire, or diamond.

As shown in FIG. 2A, a semiconductor region 202 is formed (e.g., grown or deposited) on a donor substrate 200. In some examples, the donor substrate 200 may comprise silicon, silicon carbide (SiC), sapphire, or diamond, and the semiconductor region 202 may comprise a 3-5 semiconductor, for example, gallium nitride (GaN), aluminum gallium nitride (AlGaN), gallium arsenide (GaAs), or indium phosphide (InP). In some examples, the semiconductor region 202 may have a vertical (z-direction) thickness in the range of 1-10 microns (μm), e.g., depending on the material of the underlying donor substrate 200.

As shown in FIG. 2B, an ion implant (e.g., a hydrogen (H₂) ion implant) is performed in the semiconductor region 202 at an ion implant depth ID indicated by the dashed line.

As shown in FIG. 2C, an array of cavities 206 is formed in the semiconductor region 202. In some examples, the cavities 206 are formed using a plasma etch (dry etch) or a wet etch. In some examples, the cavities 206 may have a vertical (z-direction) depth extending partially through the vertical thickness of the semiconductor region 202. In some examples, respective cavities 206 have a vertical (z-direction) depth in the range of 50-500 nm (500-5000 Å), wherein the depth may depend on materials of the semiconductor region 202 and/or underlying donor substrate 200. Respective cavities 206 may be formed with any suitable shape or shapes, e.g., elongated trenches (e.g., elongated in the x-direction or y-direction extending into the page), cylinders, etc.

In some examples, the array of cavities 206 may be formed at a lateral location (in the x-direction and/or y-direction) selected such that the resulting enclosed voids 102 (i.e., formed by enclosing cavities 206, as discussed below) of the formed HEMT transistor device 100 are located closer to the transistor source 112 than the drain 114, e.g., to reduce gate-source capacitance C_{gs} in the HEMT transistor device 100.

As shown in FIG. 2D, the transistor substrate 108 is bonded (e.g., vacuum bonded) on the semiconductor region 202 to vacuum seal or otherwise enclose the array of cavities 206, thereby forming the array of enclosed voids 102. As noted above, in some examples, the transistor substrate 108 may comprise silicon carbide (SiC), high lattice defect density (HLDD) SiC, poly-SiC, or silicon.

As shown in FIG. 2E, an anneal is performed, which causes the structure to separate (cleave) at or near the ion implant depth ID in the semiconductor region 202, thereby separating (a) the transistor substrate 108 and a first portion 202a of the semiconductor region 202 including the array of enclosed voids 102 from (b) the donor substrate 200 and a second portion 202b of the semiconductor region 202. For example, the anneal may form bubbles in the semiconductor region 202 at the ion implant depth ID, causing or facilitating a separation of the structure. The donor substrate 200 and second portion 202b of the semiconductor region 202 may be reused for a next cycle, which may include growing an additional thickness of semiconductor material before reuse.

As shown in FIG. 2F, the transistor substrate 108 and first portion 202a of the semiconductor region 202 including the array of enclosed voids 102 may be flipped over, and an exposed surface of the semiconductor region 202a may be processed. For example, the exposed surface of the semiconductor region 202a (indicated at 212 in FIG. 2E), which may be rough after the separation process, may be polished and planarized (e.g., by performing a chemical mechanical planarization (CMP) and clean), following by growing an additional thickness of semiconductor material 214 (e.g., the same material as the semiconductor region 202a) on the processed surface 212, resulting in the semiconductor buffer layer 106 discussed above.

Finally, as shown in FIG. 2G, the HEMT transistor 100 may be formed on the transistor substrate 108 and semiconductor buffer layer 106, for example by forming the gate dielectric layer 110 over the semiconductor buffer layer 106 to define a 2DEG channel region 104 over the array of enclosed voids 102 in the semiconductor buffer layer 106, and forming the source 112, drain 114, and gate 116 structures.

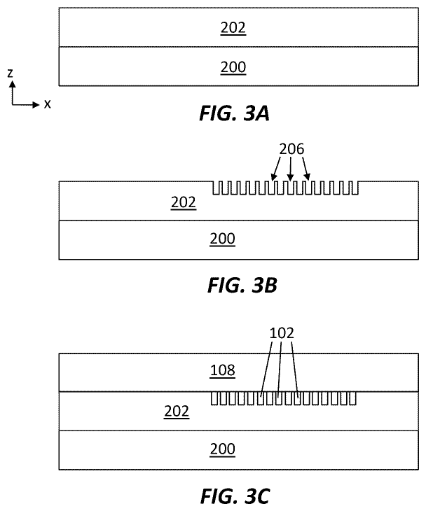

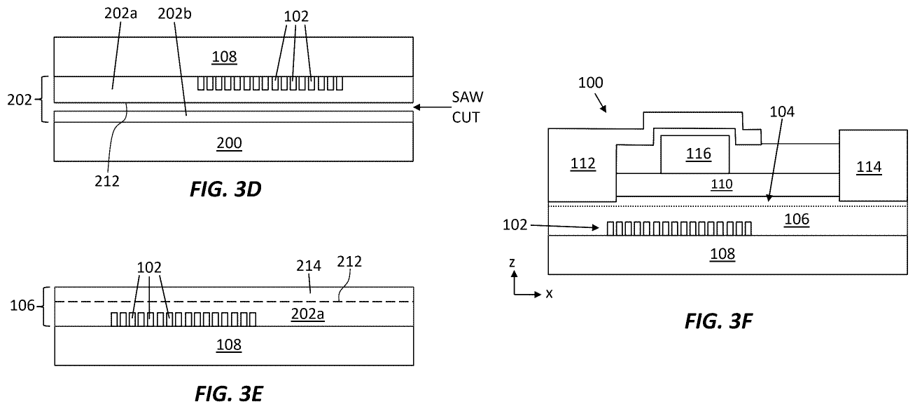

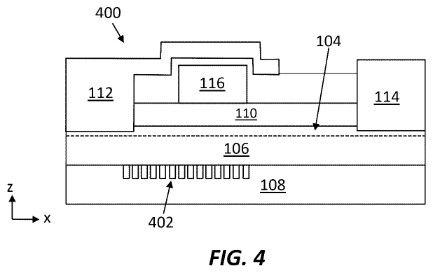

FIGS. 3A-3F show a series of a cross-sectional side views illustrating another example method of forming the example HEMT transistor device 100 shown in FIG. 1, i.e., including the array of enclosed voids 102 below the 2DEG channel region 104. The example method of FIGS. 3A-3F may be similar to the example method of FIGS. 2A-2G discussed above, except the separation of the structure may be performed by a mechanical saw cut (as shown in FIG. 3D) instead of the ion implant and anneal processor discussed above.

As shown in FIG. 3A, a semiconductor region 202 is formed (e.g., grown or deposited) on a donor substrate 200, e.g., as described above regarding FIG. 2A.

As shown in FIG. 3B, an array of cavities 206 is formed in the semiconductor region 202, e.g., as described above regarding FIG. 2C.

As shown in FIG. 3C, the transistor substrate 108 is bonded (e.g., vacuum bonded) on the semiconductor region 202 to vacuum seal or otherwise enclose the array of cavities 206, thereby forming the array of enclosed voids 102, e.g., as described above regarding FIG. 2D.

As shown in FIG. 3D, a mechanical cutting is performed through the semiconductor layer 202 to separate (a) the transistor substrate 108 and first portion 202a of the semiconductor region 202 including the array of enclosed voids 102 from (b) the donor substrate 200 and second portion 202b of the semiconductor region 202. The mechanical cutting may comprise a saw cut or other cutting process. The donor substrate 200 and second portion 202b of the semiconductor region 202 may be reused for a next cycle, which may include growing an additional thickness of semiconductor material before reuse.

As shown in FIG. 3E, the transistor substrate 108 and first portion 202a of the semiconductor region 202 including the array of enclosed voids 102 may be flipped over, and an exposed surface of the semiconductor region 202a may be processed, e.g., including polishing and planarizing (e.g., by performing a CMP and clean) the exposed surface 212 of the semiconductor region 202a, following by growing an additional thickness of semiconductor material 214 (e.g., the same material as the semiconductor region 202a) on the processed surface 212, resulting in the semiconductor buffer layer 106 discussed above.

Finally, as shown in FIG. 3F, the HEMT transistor 100 may be formed on the transistor substrate 108 and semiconductor buffer layer 106, for example by forming the gate dielectric layer 110 over the semiconductor buffer layer 106 to define a 2DEG channel region 104 over the array of enclosed voids 102 in the semiconductor buffer layer 106, and forming the source 112, drain 114, and gate 116 structures.

FIG. 4 is a cross-sectional side view of an example HEMT transistor device 400 including enclosed voids 402 formed below a 2DEG channel region 104, e.g., to reduce an output capacitance of the HEMT transistor device 100. Like the example HEMT transistor device 100 discussed above, HEMT transistor device 400 includes semiconductor buffer layer 106 formed on transistor substrate 108, gate dielectric layer 110 formed over the semiconductor buffer layer 106, source 112, drain 114, and gate 116, wherein the gate dielectric layer 110 formed over the semiconductor buffer layer 106 define the 2DEG channel region 104 between the source 112 and drain 114.

The example HEMT transistor device 400 may be similar to the example HEMT transistor device 100 discussed above, except the enclosed voids 402 are formed in the transistor substrate 108 in contrast with the enclosed voids 102 formed in the semiconductor buffer layer 106 of the example HEMT transistor device 100.

As shown, respective enclosed voids 402 may extend partially through the thickness of the transistor substrate 108 in a direction perpendicular to a planar interface PI between the semiconductor buffer layer 106 and transistor substrate 108, i.e., in a vertical direction (z-direction) in the orientation shown in FIG. 4. In some examples, respective enclosed voids 402 have a vertical depth (i.e., in the z-direction) in the range of 50-500 nm (500-5000 Å). In addition, in some examples, the enclosed voids 402 may cover less than 50% of a lateral footprint (i.e., in the x-y plane) of a region of the semiconductor buffer layer 106 between the source 112 and drain 114.

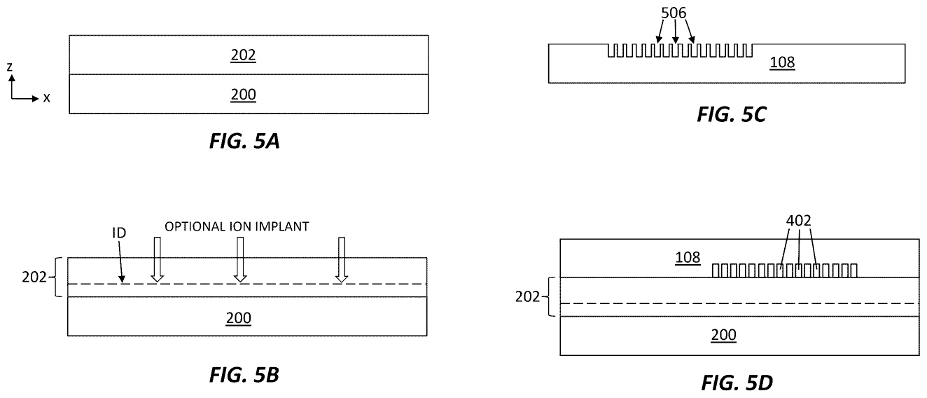

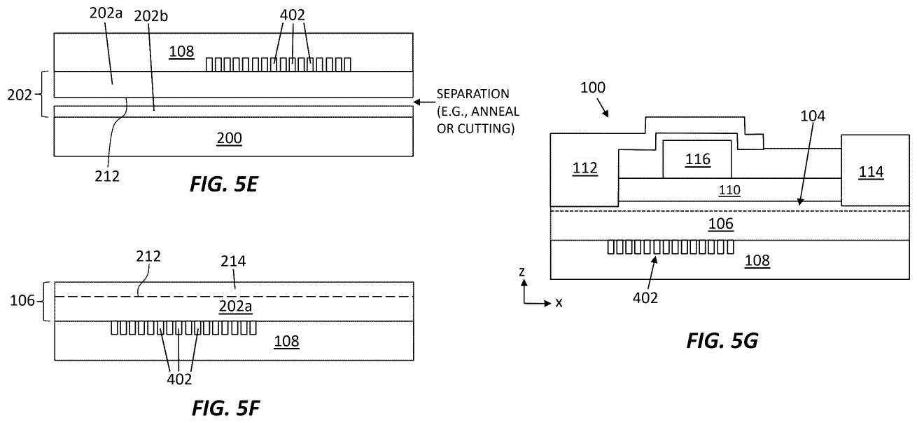

FIGS. 5A-5G show a series of a cross-sectional side views illustrating an example method of forming the example HEMT transistor device 400 shown in FIG. 4, i.e., including the array of enclosed voids 102 formed in the transistor substrate 108.

As shown in FIG. 5A, a semiconductor region 202 is formed (e.g., grown or deposited) on a donor substrate 200, e.g., as described above regarding FIG. 2A.

FIG. 5B shows an optional ion implant (e.g., a hydrogen (H₂) ion implant) performed in the semiconductor region 202 at an ion implant depth ID indicated by the dashed line. The optional ion implant may facilitate a subsequent separation of the structure through the semiconductor region 202, e.g., by performing an anneal as discussed above regarding FIG. 2E and below regarding FIG. 5E. Alternatively, the optional ion implant may be omitted in implementations in which a mechanical process (e.g., saw cut) is used to separate the structure, as discussed below regarding FIG. 5E.

As shown in FIG. 5C, a transistor substrate 108 is provided, and an array of cavities 506 are formed in the transistor substrate 108. The array of cavities 506 may be similar to the array of cavities 206 discussed above, but formed in the transistor substrate 108 instead of the semiconductor region 202. Thus, the cavities 506 may be formed using a plasma etch (dry etch) or a wet etch, and may have a vertical (z-direction) depth extending partially through the vertical thickness of the transistor substrate 108, e.g., with a depth in the range of 50-500 nm (500-5000 Å). Respective cavities 506 may be formed with any suitable shape or shapes, e.g., elongated trenches (e.g., elongated in the x-direction or y-direction extending into the page), cylinders, etc.

In some examples, the array of cavities 506 may be formed at a lateral location (in the x-direction and/or y-direction) selected such that the resulting enclosed voids 402 (i.e., formed by enclosing cavities 506, as discussed below) of the formed HEMT transistor device 400 are located closer to the transistor source 112 than the drain 114, e.g., to reduce gate-source capacitance C_{gs} in the HEMT transistor device 400.

As shown in FIG. 5D, the transistor substrate 108 including the array of cavities 506 is bonded (e.g., vacuum bonded) on the semiconductor region 202 to vacuum seal or otherwise enclose the array of cavities 506, thereby forming the array of enclosed voids 402

As shown in FIG. 5E, a separation process is performed to separate (a) the transistor substrate 108 including the array of enclosed voids 402 and a first portion 202a of the semiconductor region 202 from (b) the donor substrate 200 and second portion 202b of the semiconductor region 202. In some implementations, e.g., wherein the optional ion implant shown in FIG. 5B is performed, the separation process may comprise an anneal, which causes or facilitates a separation of the semiconductor region 202 at the ion implant depth ID. In other implementations, e.g., wherein the optional ion implant is omitted, the separation process may comprise a mechanical separation, e.g., a saw cut process. As discussed above, the donor substrate 200 and second portion 202b of the semiconductor region 202 may be reused for a next cycle, which may include growing an additional thickness of semiconductor material before reuse.

As shown in FIG. 5F, the transistor substrate 108 (including the array of enclosed voids 402) and first portion 202a of the semiconductor region 202 may be flipped over, and an exposed surface of the semiconductor region 202a may be processed, e.g., including polishing and planarizing (e.g., by performing a CMP and clean) the exposed surface 212 of the semiconductor region 202a, following by growing an additional thickness of semiconductor material 214 (e.g., the same material as the semiconductor region 202a) on the processed surface 212, resulting in the semiconductor buffer layer 106 discussed above.

Finally, as shown in FIG. 5G, the HEMT transistor 400 may be formed on the transistor substrate 108 and semiconductor buffer layer 106, for example by forming the gate dielectric layer 110 over the semiconductor buffer layer 106 to define a 2DEG channel region 104 over the array of enclosed voids 402 in the transistor substrate 108, and forming the source 112, drain 114, and gate 116 structures.

Although example embodiments have been described above, other variations and embodiments may be made from this disclosure without departing from the spirit and scope of these embodiments.

1. A method, comprising:
forming a semiconductor layer on a donor substrate, the semiconductor layer comprising a semiconductor material;
forming an array of cavities in the semiconductor layer;
bonding a transistor substrate to the semiconductor layer, wherein the transistor substrate encloses the array of cavities to form an array of enclosed voids;
performing a separation process to separate (a) the transistor substrate and a first portion of the semiconductor layer including the array of enclosed voids from (b) the donor substrate and a second portion of the semiconductor layer; and
using the transistor substrate and the first portion of the semiconductor layer to form a high-electron-mobility transistor (HEMT) device with a two-dimensional electron gas (2DEG) channel region over the array of enclosed voids.

2. The method of claim 1, wherein forming the HEMT transistor device comprises:
processing the first portion of the semiconductor layer including the array of enclosed voids to form a semiconductor buffer layer; and
forming a gate dielectric layer over the semiconductor buffer layer to define the 2DEG channel region over the array of enclosed voids.

3. The method of claim 2, wherein processing the first portion of the semiconductor layer including the array of enclosed voids to form a semiconductor buffer layer comprises growing an additional thickness of the semiconductor material.

4. The method of claim 1, comprising performing an ion implant at an implant depth in the semiconductor layer prior to bonding the transistor substrate to the semiconductor layer; and
wherein the separation process comprises performing an anneal to effect a separation of the semiconductor layer at the implant depth.

5. The method of claim 1, wherein the separation process comprises a mechanical cutting through the semiconductor layer.

6. The method of claim 1, comprising performing an etch process to form the array of cavities in the semiconductor layer.

7. The method of claim 1, wherein respective cavities in the array of cavities extend through a partial thickness of the semiconductor layer in a direction perpendicular to an interface between the semiconductor layer and the donor substrate.

8. The method of claim 1, wherein respective cavities are formed with a depth in a range of 50-500 nm in a direction perpendicular to an interface between the semiconductor layer and the donor substrate.

9. The method of claim 1, wherein the semiconductor layer comprises gallium nitride (GaN), aluminum gallium nitride (AlGaN), gallium arsenide (GaAs), or indium phosphide (InP).

10. A method, comprising:
forming a semiconductor layer on a donor substrate, the semiconductor layer comprising a semiconductor material;
forming an array of cavities in a transistor substrate;
bonding the transistor substrate including the array of cavities to the semiconductor layer, wherein the semiconductor layer encloses the array of cavities to form an array of enclosed voids;
performing a separation process to separate (a) the transistor substrate including the array of enclosed voids and a first portion of the semiconductor layer from (b) the donor substrate and a second portion of the semiconductor layer; and
using the transistor substrate including the array of enclosed voids and the first portion of the semiconductor layer to form a high-electron-mobility transistor (HEMT) device including a two-dimensional electron gas (2DEG) channel region over the array of enclosed voids.

11. The method of claim 10, wherein forming the HEMT transistor device comprises:
growing an additional thickness of the semiconductor material on the first portion of the semiconductor layer to form a semiconductor buffer layer; and
forming a gate dielectric layer over the semiconductor buffer layer to define the 2DEG channel region over the array of enclosed voids in the transistor substrate.

12. The method of claim 10, comprising performing an ion implant at an implant depth in the semiconductor layer prior to bonding the transistor substrate to the semiconductor layer; and
wherein the separation process comprises performing an anneal to effect a separation of the semiconductor layer at the implant depth.

13. The method of claim 10, wherein the separation process comprises a mechanical cutting through the semiconductor layer.

14. A device, comprising:
a semiconductor buffer layer formed on a substrate;
a gate dielectric layer formed over the semiconductor buffer layer;
a source, a drain, and a gate;
wherein the gate dielectric layer defines a two-dimensional electron gas (2DEG) channel region in the semiconductor buffer layer; and
an array of enclosed voids formed below the 2DEG channel region.

15. The device of claim 14, wherein the device comprises a high-electron-mobility transistor (HEMT) device.

16. The device of claim 14, wherein the array of enclosed voids are formed in the semiconductor buffer layer.

17. The device of claim 16, wherein respective cavities in the array of cavities extend through a partial thickness of the semiconductor buffer layer in a direction perpendicular to an interface between the semiconductor buffer layer and the substrate.

18. The device of claim 14, wherein the array of enclosed voids are formed in the substrate.

19. The device of claim 18, wherein respective cavities in the array of cavities extend through a partial thickness of the substrate in a direction perpendicular to an interface between the semiconductor buffer layer and the substrate.

20. The device of claim 14, wherein the semiconductor buffer layer comprises gallium nitride (GaN), aluminum gallium nitride (AlGaN), gallium arsenide (GaAs), or indium phosphide (InP).
